(19) United States
(12) Patent Application Publication
(10) Pub. No.: US 2008/0000679 A1
(43) Pub. Date: Jan. 3, 2008

(54) Wired circuit board and producing method thereof

(75) Inventors: Katsutoshi Kamei, Osaka (JP); Jun Ishii, Osaka (JP); Yasunari Ooyabu, Osaka (JP); Visit Thaveeprungsriporn, Osaka (JP)

Correspondence Address: AKERMAN SENTERFITT, 801 PENNSYLVANIA AVENUE N.W., SUITE 600, WASHINGTON, DC, 20004, US

(73) Assignee: Nitto Denko Corporation, Osaka (JP)

(21) Appl. No.: 11/808,474

(22) Filed: Jun. 11, 2007

Related U.S. Application Data
(60) Provisional application No. 60/815,275, filed on Jun. 21, 2006.

(30) Foreign Application Priority Data
Jun. 9, 2006 (JP) 2006-161116

(51) Int. Cl. B32B 3/00; H05K 1/03

(52) U.S. Cl. 174/262; 428/209; 428/901; 174/255; 174/260; 29/830; 29/846

(57) ABSTRACT

A wired circuit board has an insulating layer and a conductive pattern formed on the insulating layer and made of a copper alloy in which silver is diffused, wherein a content ratio of the silver contained in the copper alloy is more than 0.50% by weight and not more than 3.00% by weight

### CROSS-REFERENCE TO RELATED APPLICATION

This patent application claims the benefit of U.S. Provisional Application No. 60/815,275, filed on Jun. 21, 2006, and claims priority from Japanese Patent Application No. 2006-161116, filed on Jun. 9, 2006, the contents of which are herein incorporated by reference in their entirety.

### BACKGROUND OF THE INVENTION

1. Field of the Invention

The present invention relates to a wired circuit board and a producing method thereof and, more particularly, to a wired circuit board used for a flexible wired circuit board, a suspension board with circuit, or the like and a producing method thereof.

2. Description of Related Art

In a wired circuit board such as a flexible wired circuit board, it has been known to use a copper alloy obtained by adding silver to copper as a metal for forming a conductive pattern.

For example, it has been proposed to add molten silver to molten copper, cast the molten copper containing the silver at a content ratio of 0.07% to 0.5% by weight into an ingot, roll the ingot into a copper foil for a flexible copper-clad laminate, to enhance the strength of the rolled copper foil (see, e.g., Japanese Unexamined Patent Publication No. 2003-96526).

It has also been proposed to successively laminate a silver coating and a copper plating layer on an interlayer insulating layer in fine circuit wiring, diffuse silver contained in the silver coating into copper contained in the copper plating layer by thermally treating the resulting laminate to prevent migration in copper wiring (see, e.g., Japanese Unexamined Patent Publication No. 2003-328184).

### SUMMARY OF THE INVENTION

With the recent trend toward a finer wiring pitch, a further improvement is required for the strength of wiring. However, it is sometimes difficult that the rolled copper foil for a flexible copper-clad laminate disclosed in Japanese Unexamined Patent Publication No. 2003-96526 sufficiently suffices such a requirement.

The fine circuit wiring disclosed in Japanese Unexamined Patent Publication No. 2003-328184 intends to prevent migration in the copper wiring, but not the strength of the wiring. To improve the strength of the wiring, further study is required.

It is therefore an object of the present invention to provide a wired circuit board which allows a sufficient improvement in the strength of a conductive pattern and a producing method thereof.

A wired circuit board according to the present invention comprises an insulating layer, and a conductive pattern formed on the insulating layer and made of a copper alloy in which silver is diffused, wherein a content ratio of the silver contained in the copper alloy is more than 0.50% by weight and not more than 3.00% by weight.

In the wired circuit board according to the present invention, it is preferable that the conductive pattern is obtained by laminating a silver layer and a copper layer on the insulating layer, and heating a resulting laminate thereafter.

In the wired circuit board according to the present invention, it is preferable that the conductive pattern is obtained by laminating a first copper layer, a silver layer and a second copper layer successively on the insulating layer, and heating a resulting laminate thereafter.

The wired circuit board according to the present invention comprises the conductive pattern made of the copper alloy in which silver is diffused, wherein the content ratio of the silver contained in the copper alloy is more than 0.50% by weight and not more than 3.00% by weight. This allows a sufficient improvement in the strength of the conductive pattern. As a result, a wired circuit board with high connection reliability can be obtained.

A method of producing a wired circuit board according to the present invention comprises the steps of preparing an insulating layer, laminating a silver layer and a copper layer on the insulating layer, and forming a conductive pattern made of a copper alloy by heating the silver layer and the copper layer to diffuse the silver in the copper, wherein a content ratio of the silver contained in the copper alloy is more than 0.50% by weight and not more than 3.00% by weight.

A method of producing a wired circuit board according to the present invention comprises the steps of preparing an insulating layer, laminating a first copper layer, a silver layer and a second copper layer successively on the insulating layer, and forming a conductive pattern made of a copper alloy by heating the first copper layer, the silver layer and the second copper layer to diffuse the silver in the copper, wherein a content ratio of the silver contained in the copper alloy is more than 0.50% by weight and not more than 3.00% by weight.

In the method of producing a wired circuit board according to the present invention, the conductive pattern made of the copper alloy in which silver is diffused is formed, wherein the content ratio of the silver contained in the copper alloy is more than 0.50% by weight and not more than 3.00% by weight. This allows a sufficient improvement in the strength of the conductive pattern. As a result, a wired circuit board with high connection reliability can be obtained.

### BRIEF DESCRIPTION OF THE DRAWINGS

FIG. 1 shows a widthwise cross section in a production process diagram for showing a method of producing a wired circuit board according to an embodiment of the present invention,

(a) showing the step of preparing an insulating base layer,

(b) showing the step of successively laminating a silver layer and a copper layer on the insulating base layer,

(c) showing the step of forming a conductive pattern made of a copper alloy in which silver is diffused by heating the silver layer and the copper layer, and

(d) showing the step of forming an insulating cover layer on the insulating base layer to cover the conductive pattern;

FIG. 2 is a process step diagram for illustrating the step (b) of successively laminating a silver layer and a copper layer on an insulating base layer and the step (c) of forming a conductive pattern made of a copper alloy in which silver is diffused by heating the silver layer and the copper layer in the widthwise cross section of the production process diagram shown in FIG. 1,

(a) showing the step of preparing the insulating base layer,

(b) showing the step of forming a metal thin film on the entire surface of the insulating base layer,

(c) showing the step of forming a plating resist on the surface of the metal thin film,

(d) showing the step of laminating the silver layer on the surface of the metal thin film exposed from the plating resist,

(e) showing the step of laminating the copper layer on the surface of the silver layer,

(f) showing the step of removing the plating resist and the metal thin film, and

(g) showing the step of forming the conductive pattern made of the copper alloy in which the silver is diffused by heating the silver layer and the copper layer;

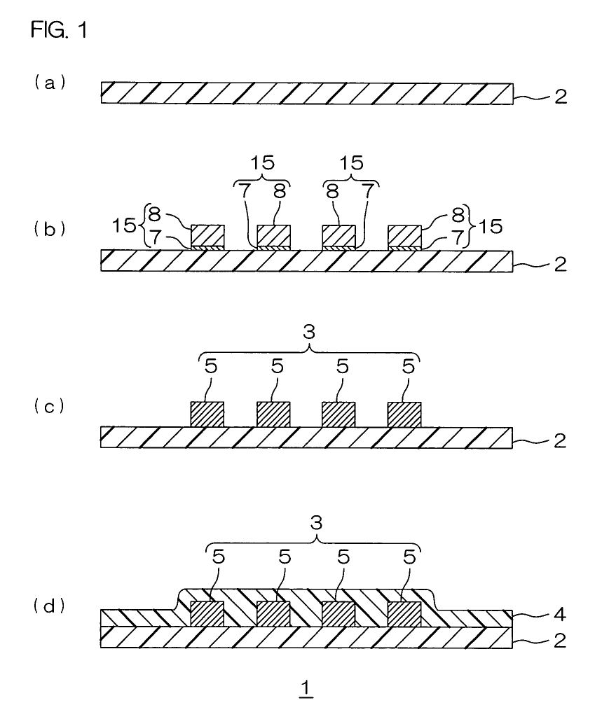

FIG. 3 shows a widthwise cross section in a process of the production of a wired circuit board according to another embodiment of the present invention showing the step (corresponding to FIG. 1(b)) of successively laminating a copper layer and a silver layer on an insulating base layer;

FIG. 4 shows a widthwise cross section in a process of the production of a wired circuit board according to still another embodiment of the present invention showing the step (corresponding to FIG. 1(b)) of successively laminating a first copper layer, a silver layer, and a second copper layer on an insulating base layer;

FIG. 5 shows a widthwise cross section in a process of the production of a wired circuit board according to yet another embodiment of the present invention showing the step (corresponding to FIG. 1(b)) of successively laminating a first copper layer, a first silver layer, a second copper layer, a second silver layer, and a third copper layer on an insulating base layer; and

FIG. 6 shows a widthwise cross-sectional view at the terminal portions of a suspension board with circuit according to still another embodiment of the wired circuit board of the present invention.

### DETAILED DESCRIPTION OF THE INVENTION

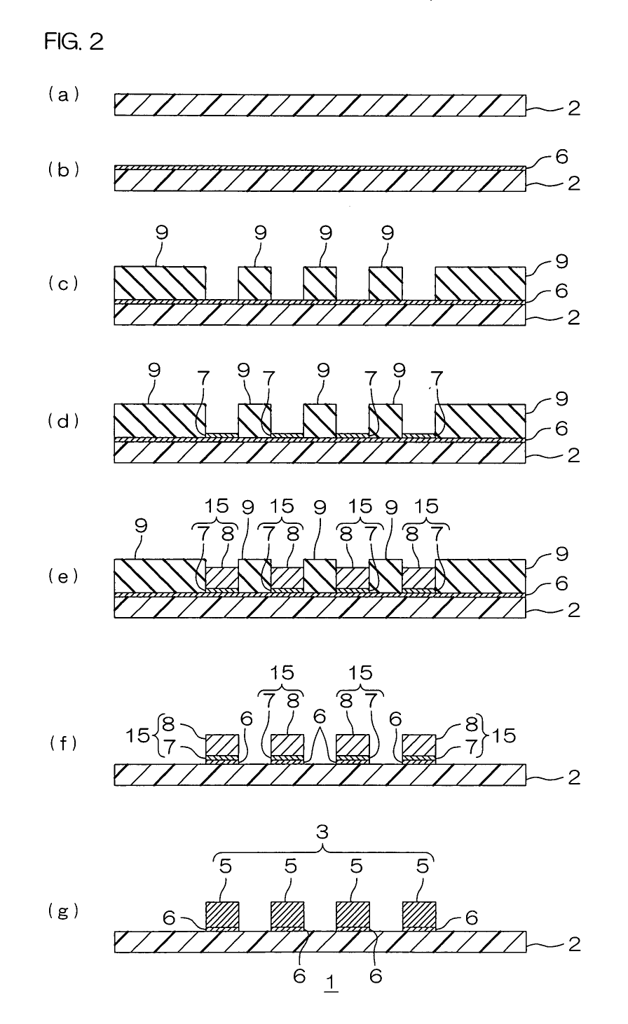

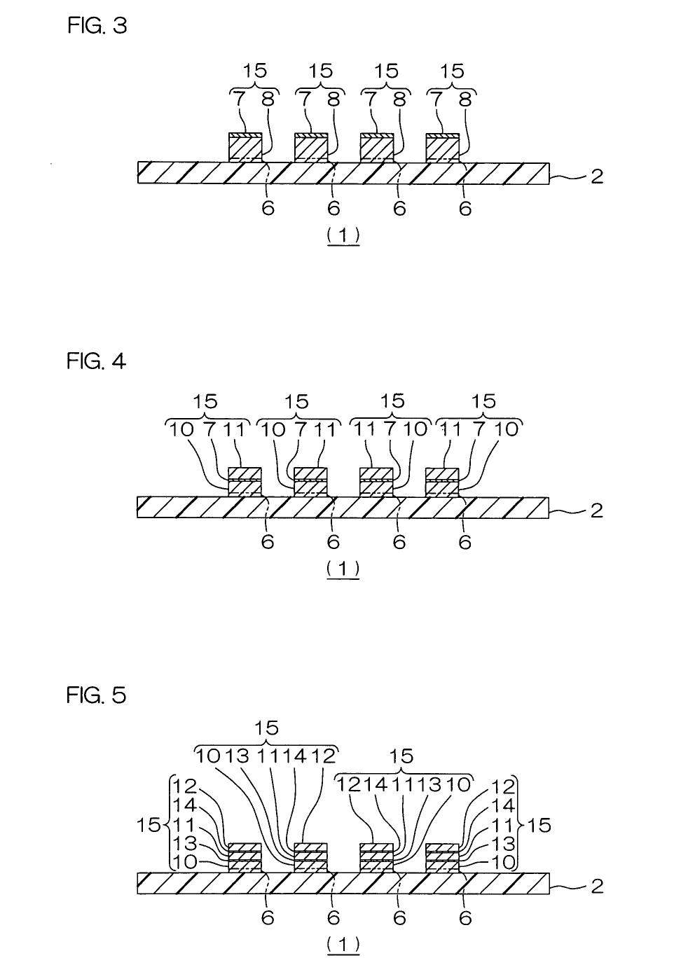

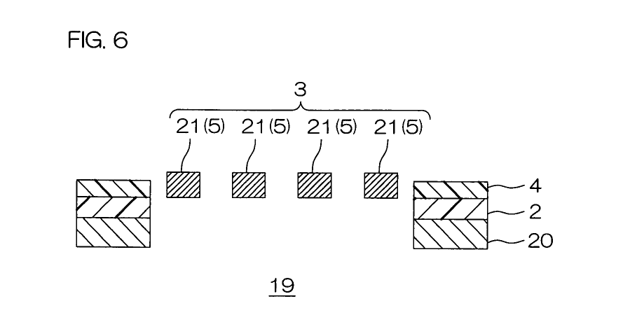

FIG. 1 shows a widthwise cross section in a production process diagram for showing a method of producing a wired circuit board according to an embodiment of the present invention. In FIG. 1, a metal thin film 6 (see FIG. 2(b)) described later is omitted.

The wired circuit board 1 is a flexible wired circuit board formed in the shape of a flat belt extending in the longitudinal direction. As shown in, e.g., FIG. 1(d), the wired circuit board 1 comprises an insulating base layer 2 as an insulating layer, a conductive pattern 3 formed on the insulating base layer 2, and an insulating cover layer 4 formed on the insulating base layer 2 to cover the conductive pattern 3.

The insulating base layer 2 is formed in the shape of a flat belt corresponding to the outer shape of the wired circuit board 1.

The conductive pattern 3 comprises a plurality of wires 5 extending along the longitudinal direction of the wired circuit board 1 and arranged in mutually spaced-apart and parallel relation in a widthwise direction (orthogonal to the longitudinal direction of the wired circuit board 1). The conductive pattern 3 is formed of a copper alloy in which silver is diffused and contained at a content ratio of more than 0.50% by weight and not more than 3.00% by weight by a producing method described later.

The conductive pattern 3 includes terminal portions, which are not shown, for connecting to the external terminals of an electric component, which is not shown.

In the insulating cover layer 4, openings, which are not shown, are formed to expose the terminal portions.

Next, the method of producing the wired circuit board 1 is described with reference to FIGS. 1 and 2.

In the method, the insulating base layer 2 is prepared first, as shown in FIG. 1(a). For the insulating base layer 2, there is used a film of a synthetic rein such as, e.g., a polyimide resin, a polyamide-imide resin, an acrylic resin, a polyether nitrile resin, a polyether sulfone resin, a polyethylene terephthalate resin, a polyethylene naphthalate resin, or a polyvinyl chloride resin. Preferably, a film of a polyimide resin is used.

The insulating base layer 2 is either prepared in advance as a film of a synthetic resin or prepared by forming a varnish of a synthetic resin into a film by casting on a stripper board, which is not shown and drying the film, and curing as necessary. Alternatively, the insulating base layer 2 is prepared by forming (coating) a varnish of a photosensitive synthetic resin into a film by casting on a stripper board, drying, exposing to light, developing, and processing the film into the foregoing pattern, and curing as necessary. The thickness of the insulating base layer 2 is in the range of, e.g., 3 to 50 μm, or preferably 5 to 30 μm.

Then, a silver layer 7 and a copper layer 8 are successively laminated on the insulating base layer 2 to form a laminate metal layer 15, as shown in FIG. 1(b).

The silver layer 7 and the copper layer 8 formed as the laminate metal layer 15 are successively formed as the foregoing wired circuit pattern by a known patterning method such as, e.g., a subtractive method or an additive method, or preferably by an additive method in terms of forming a fine wiring pattern.

In the additive method, the metal thin film 6 as a seed film is formed first on the entire surface of the insulating base layer 2, as shown in FIGS. 2(a) and 2(b). The metal thin film 6 is formed of chromium, nickel, copper, or an alloy thereof by a thin film formation method such as a sputtering method. More specifically, e.g., a chromium thin film and a copper thin film are successively formed on the entire insulating base layer 2 by a sputter vapor-deposition method. In the formation of the metal thin film 6, the thickness of the chromium thin film is set to, e.g., 10 to 60 nm and the thickness of the copper thin film is set to, e.g., 50 to 200 nm.

Then, as shown in FIG. 2(c), a plating resist 9 is formed in a pattern reverse to the conductive pattern 3 on the surface of the metal thin film 6. The plating resist 9 is formed from a dry film photoresist or the like by a known method involving exposure to light and development.

Then, as shown in FIG. 2(d), the silver layer 7 is formed (laminated) on the surface of the metal thin film 6 exposed from the plating resist 9. The silver layer 7 is formed by a vapor deposition method such as, e.g., a vacuum vapor deposition, an ion plating method, or a sputtering method, a plating method such as, e.g., an electrolytic plating method or an electroless plating method, or the like. Preferably, the silver layer 7 is formed by a silver sputtering method or an electroless silver plating method.

In the silver sputtering method, the silver layer 7 is formed by, e.g., sputtering silver as a target and introducing an inert gas, such as argon, as an introduced gas.

In the electroless silver plating method, the silver layer 7 is formed by dipping the wired circuit board 1 in a process of the production shown in FIG. 2(c) in a silver plating solution.

The thickness of the silver layer 7 is selected appropriately depending on a weight ratio of silver diffused in the copper alloy described later. The thickness of the silver layer 7 is in the range of, e.g., 10 to 600 nm, preferably 10 to 200 nm, or more preferably 10 to 160 nm. When the silver layer 7 is formed as a plurality of silver layers as described later, the total thickness is preferably set to fall in the thickness range shown above.

Then, as shown in FIG. 2(e), the copper layer 8 is formed (laminated) on the surface of the silver layer 7. The copper layer 8 is formed by the same vapor deposition method or plating method as used to form the silver layer 7, or preferably by an electrolytic copper plating method.

In the electrolytic copper plating method, the copper layer 8 is formed by, e.g., dipping the wired circuit board 1 in a process of the production shown in FIG. 2(d) in an electrolytic copper sulfate plating solution and conducting an electric current having a predetermined value.

The thickness of the copper layer 8 is selected appropriately in accordance with a thickness required for the conductive pattern 3. For example, the thickness of the copper layer 8 is in the range of, e.g., 4 to 20 μm, preferably 7 to 15 μm, or more preferably 8 to 12 μm. When the copper layer 8 is formed as a plurality of copper layers as described later, the total thickness is preferably set to fall in the thickness range shown above.

Then, as shown in FIG. 2(f), the metal resist 9 is removed by etching or stripping and then the metal thin film 6 exposed from the laminate metal layer 15 is removed by etching.

As a result, as shown in FIG. 1(b) and more specifically shown in FIG. 2(f), the laminate metal layer 15 composed of the silver layer 7 and the copper layer 8 successively laminated can be formed in the wired circuit pattern on the insulating base layer 2 (metal thin film 6).

Then, as shown in FIG. 1(c) and more specifically shown in FIG. 2(g), the laminate metal layer 15 is heated to form the conductive pattern 3 made of the copper alloy in which silver is diffused.

The laminate metal layer 15 is heated in an oxygen-containing atmosphere such as atmospheric air or in an inert gas atmosphere of, e.g., nitrogen, or preferably in an inert gas atmosphere in a temperature range of, e.g., 300 to 600° C., or preferably 350 to 400° C. for a period of, e.g., 60 to 300 minutes, or preferably 120 to 300 minutes.

By such heating, the silver contained in the silver layer 7 of the laminate metal layer 15 is diffused into the copper layer 8 so that the laminate metal layer 15 forms the conductive pattern 3 made of the copper alloy in which the silver is diffused.

In the conductive pattern 3 (copper alloy), the weight ratio of silver (silver concentration) diffused therein is, e.g., more than 0.50% by weight and not more than 3.00% by weight, preferably more than 0.50% by weight and not more than 1.50% by weight, or more preferably more than 0.50% by weight and not more than 1.00% by weight. When the weight ratio of the diffused silver is not more than 0.50% by weight, the strength of the conductive pattern 3 cannot be sufficiently improved. When the weight ratio of the diffused silver is more than 3.00% by weight, all of the silver contained in the silver layer 7 is not efficiently diffused in the copper alloy so that the silver layer 7 remains.

The weight ratio of the silver diffused in the conductive pattern 3 is calculated from the thickness of the silver layer 7, the thickness of the copper layer 8, the concentration of silver, and the concentration of copper before heating. That is, the weight ratio of the silver is calculated in accordance with the following formula:

Weight Ratio of Silver (wt %)=(Thickness of Silver Layer 7 per Unit Area×Silver Concentration)/{(Thickness of Silver Layer 7 per Unit Area×Silver Concentration)+(Thickness of Copper Layer 8 per Unit Area×Concentration of Copper Layer 8)}×100.

In the obtained conductive pattern 3, the silver is diffused to have a distribution in the thickness direction (lamination direction) such that the weight ratio of silver is highest in the lowermost portion and gradually decreases according to the distance from the lowermost portion toward an upper portion in the thickness direction.

The thickness of the conductive pattern 3 is in the range of, e.g., 4 to 20 μm, preferably 7 to 15 μm, or more preferably 8 to 12 μm.

Then, as shown in FIG. 1(d), the insulating cover layer 4 is formed on the insulating base layer 2 to cover the conductive pattern 3 and form openings in which the terminal portions (not shown) are exposed, whereby the wired circuit board 1 is obtained.

For the insulating cover layer 4, the same synthetic resin as used for the insulating base layer 2 is used. The insulating cover layer 4 can be formed in the foregoing pattern by, e.g., forming (coating) a varnish of a photosensitive resin into a film by casting, drying, exposing to light, and developing the film, and curing film as necessary.

Alternatively, the insulating cover layer 4 can also be formed by sticking a film of a synthetic resin preliminary formed in the foregoing pattern onto the insulating base layer 2 including the conductive pattern 3 via an adhesive layer as necessary.

The thickness of the insulating cover layer 4 is in the range of, e.g., 2 to 25 μm, or preferably 5 to 15 μm.

The wired circuit board 1 thus obtained comprises the conductive pattern 3 made of the copper alloy in which silver is diffused and contained at a content ratio of more than 0.50% by weight and not more than 3.00% by weight. As a result, the strength of the conductive pattern 3, e.g., the tensile strength or the like can be sufficiently improved. Therefore, the wired circuit board 1 with high connection reliability can be obtained.

FIGS. 3 to 5 show widthwise cross sections in a process of the production of wired circuit boards according to other embodiments of the present invention each in the step (corresponding to FIG. 1(b)) of laminating a silver layer and a copper layer on an insulating base layer.

More specifically, FIG. 3 shows the step of successively laminating a copper layer and a silver layer on an insulating base layer, FIG. 4 shows the step of successively laminating a first copper layer, a silver layer, and a second copper layer on an insulating base layer, and FIG. 5 shows the step of successively laminating a first copper layer, a first silver layer, a second copper layer, a second silver layer, and a third copper layer on an insulating base layer.

In each of FIGS. 3 to 5, the metal thin film 6 formed in the case where the conductive pattern 3 is formed by an additive method is indicated by the imaginary line. For the components corresponding to the individual components described above, the detailed description is omitted using the same reference numerals in each of the subsequent drawings.

In the description given above, the laminate metal layer 15 is formed by successively laminating the silver layer 7 and the copper layer 8 on the insulating base layer 2 (metal thin film 6) in a process of the production of the wired circuit board 1. However, the laminate metal layer 15 may also be formed by, e.g., successively laminating the copper layer 8 and the silver layer 7 on the insulating base layer 2 (metal thin film 6), as shown in FIG. 3.

In the conductive pattern 3 obtained by heating the laminate metal layer 15, silver is diffused to have a distribution in the thickness direction (lamination direction) such that the weight ratio of silver is highest in the uppermost portion and gradually decreases according to the distance from the uppermost portion toward a lower portion in the thickness direction.

Although the laminate metal layer 15 is formed by laminating the single silver layer 7 and the single copper layer 8 in a process of the production of the wired circuit board 1, it is also possible to form the laminate metal layer 15 having a sandwich structure in which, e.g., the silver layer 7 is sandwiched between two copper layers, i.e., a first copper layer 10 and a second copper layer 11 over the insulating base layer 2 (metal thin film 6), as shown in FIG. 4. More specifically, the laminate metal layer 15 is formed by successively laminating the first copper layer 10, the silver layer 7, and the second copper layer 11.

In the laminate metal layer 15 having such a structure, the thickness of each of the first copper layer 10 and the second copper layer 11 is in the range of, e.g., 2 to 10 μm, preferably 3 to 7 μm, or more preferably 4 to 6 μm. The thickness of the silver layer 7 is in the range of, e.g., 10 to 600 nm, preferably 10 to 200 nm, or more preferably 10 to 160 nm.

In the conductive pattern 3 obtained by heating the laminate metal layer 15, silver is diffused to have a distribution in the thickness direction (lamination direction) such that the weight ratio of silver is highest at a midway portion (in which the silver layer 7 is laminated) in the thickness direction and gradually decreases according to the distance from the midway portion toward an upper portion and a lower portion in the thickness direction.

That is, since the silver contained in the silver layer 7 is diffused from the midway portion in the thickness direction of the laminate metal layer 15, silver can be diffused to have a more uniform distribution in the thickness direction.

Alternatively, the laminate metal layer 15 can also be formed such that a plurality of silver layers and a plurality of copper layers are alternately laminated, as shown in FIG. 5. More specifically, the laminate metal layer 15 is formed by successively laminating the first copper layer 10, a first silver layer 13, the second copper layer 11, a second silver layer 14, and a third copper layer 12 on the insulating base layer 2 (metal thin film 6).

In the laminate metal layer 15 having such a structure, the thickness of each of the first copper layer 10, the second copper layer 11, and the third copper layer 12 is in the range of, e.g., 1 to 7 μm, preferably 2 to 5 μm, or more preferably 2 to 4 μm. The thickness of the first silver layer 13 and the second silver layer 14 is in the range of, e.g., 10 to 600 nm, preferably 10 to 100 nm, or more preferably 10 to 80 nm.

In the conductive pattern 3 obtained by heating the laminate metal layer 15, silver is diffused to have a distribution in the thickness direction (lamination direction) such that the weight ratio of silver is highest in portions in the thickness direction in which the first silver layer 13 and the second silver layer 14 are laminated and gradually decreases according to the distance from the portions in the thickness direction.

That is, since the silver contained in the first silver layer 13 and the second silver layer 14 is thus formed substantially evenly in the midway portions in the thickness direction and diffused from the midway portions, the silver can be diffused to have a more uniform distribution in the thickness direction.

Although the silver layers and the copper layers are alternately laminated after the copper layer is laminated on the insulating base layer 2 (metal thin film 6) in FIGS. 4 and 5, it is also possible to alternately laminate the copper layers and the silver layers after laminating the silver layer on the insulating base layer 2 (metal thin film 6).

Although the wired circuit board according to the present invention is described above using the flexible wired circuit board as an example, the wired circuit board according to the present invention is not limited thereto. For example, the wired circuit board according to the present invention also includes a suspension board with circuit in which an insulating base layer is supported by a metal supporting board or the like.

FIG. 6 shows a widthwise cross-sectional view at the terminal portions of a suspension board with circuit according to still another embodiment of the present invention.

The terminal portions 21 of the suspension board with circuit 19 are formed in a flying lead structure. For example, as shown in FIG. 6, the terminal portions 21 are formed to have the top surfaces exposed from the insulating cover layer 4 and the back surfaces exposed from the metal supporting board 20 and the insulating base layer 2 by opening the insulating cover layer 4 at the positions corresponding to the terminal portions 21 and opening the metal supporting board 20 and the insulating base layer 2 at the same positions as the opening positions of the insulating cover layer 4.

Even when the terminal portions 21 having the both surfaces exposed are formed in the flying lead structure, the rigidity of the terminal portions 21 can be sufficiently improved since the conductive pattern 3 including the terminal portions 21 is made of a copper alloy in which silver is diffused and contained at a content ratio of more than 0.50% by weight and not more than 3.00% by weight.

### EXAMPLES

The present invention is described more specifically by showing examples and comparative examples herein below.

### Example 1

An insulating base layer made of a film of a polyimide resin having a thickness of 10 μm was prepared (see FIG. 1(a) and FIG. 2(a)).

Then, a chromium thin film having a thickness of 40 nm and a copper thin film having a thickness of 70 nm were successively laminated on the surface of the insulating base layer by a sputtering method to form a metal thin film as a seed film on the insulating base layer (see FIG. 2(b)).

Then, a plating resist was formed in a pattern reverse to a conductive pattern on the surface of the metal thin film (see FIG. 2(c)).

Then, a silver layer having a thickness of 35.0 nm was laminated on the surface of the metal thin film exposed from the plating resist by a silver sputtering method (see FIG. 2(d)).

Then, a copper layer having a thickness of 8.1 μm was laminated on the surface of the silver layer by an electrolytic copper plating method (see FIG. 2(e)).

Then, the plating resist was removed by etching and the metal thin film exposed from a laminate metal layer formed by laminating the silver layer and the copper layer was removed by etching (see FIGS. 1(b) and 2(i)).

Then, the silver contained in the silver layer was diffused into the copper layer by heating the laminate metal layer in a nitrogen atmosphere at 400° C. for 120 minutes, whereby the conductive pattern made of a copper alloy was formed (see FIG. 1(c) and FIG. 2(g)). The weight ratio of the silver diffused in the copper alloy was 0.51% by weight to the copper alloy.

Thereafter, a varnish of a photosensitive resin was coated on the insulating base layer, dried, exposed to light, developed, and then cured to form an insulating cover layer having a thickness of 5 μm on the insulating base layer such that the conductive pattern was covered therewith and openings were formed therein to expose the terminal portions (see FIG. 1(d)).

### Example 2

A wired circuit board was obtained by the same procedure as in EXAMPLE 1 except that the thickness of the silver layer was changed to 70.0 nm and the thickness of the copper layer was changed to 8.5 μm. The weight ratio of the silver diffused in the copper alloy was 0.82% by weight to the copper alloy.

### Example 3

An insulating base layer made of a film of a polyimide resin having a thickness of 10 μm was prepared (see FIG. 1(a) and FIG. 2(a)).

Then, a chromium thin film having a thickness of 40 nm and a copper thin film having a thickness of 70 nm were successively laminated on the surface of the insulating base layer by a sputtering method to form a metal thin film as a seed film on the insulating base layer (see FIG. 2(b)).

Then, a plating resist was formed in a pattern reverse to a conductive pattern on the surface of the metal thin film (see FIG. 2(c)).

Then a first copper layer having a thickness of 4.3 μm was laminated on the surface of the metal thin film exposed from the plating resist by an electrolytic copper plating method.

Then a silver layer having a thickness of 40.0 nm was laminated on the surface of the first copper layer exposed from the plating resist by an electroless silver plating method.

Then a second copper layer having a thickness of 4.6 μm was laminated on the surface of the silver layer exposed from the plating resist by an electrolytic copper plating method.

Then, the plating resist was removed by etching. Thereafter, the metal thin film exposed from the laminate metal layer formed by laminating the first copper layer, the silver layer, and the second copper layer was removed by etching (see FIG. 4).

Then, the silver contained in the silver layer was diffused into the first copper layer and the second copper layer by heating the laminate metal layer in a nitrogen atmosphere at 400° C. for 120 minutes, whereby the conductive pattern made of a copper alloy was formed (see FIG. 1(c) and FIG. 2(g)). The weight ratio of the silver diffused in the copper alloy was 0.53% by weight to the copper alloy.

Thereafter, a varnish of a photosensitive resin was coated on the insulating base layer, dried, exposed to light, developed, and then cured to form an insulating cover layer having a thickness of 5 μm on the insulating layer such that the conductive pattern was covered therewith and openings were formed therein to expose the terminal portions (see FIG. 1(d)).

### Example 4

A wired circuit board was obtained by the same procedure as in EXAMPLE 3 except that the thickness of the first copper layer was changed to 4.5 μm, the thickness of the silver layer was changed to 92.8 nm, and the thickness of the second copper layer was changed to 5.3 μm. The weight ratio of the silver diffused in the copper alloy was 0.93% by weight to the copper alloy.

### Example 5

A wired circuit board was obtained by the same procedure as in EXAMPLE 3 except that the thickness of the silver layer was changed to 155.8 nm and the thickness of the second copper layer was changed to 4.9 μm. The weight ratio of silver diffused in the copper alloy was 1.66% by weight to the copper alloy.

### Example 6

An insulating base layer made of a film of a polyimide resin having a thickness of 10 μm was prepared (see FIG. 1(a) and FIG. 2(a)).

Then, a chromium thin film having a thickness of 40 nm and a copper thin film having a thickness of 70 nm were successively formed on the surface of the insulating base layer by a sputtering method to form a metal thin film as a seed film on the insulating base layer (see FIG. 2(b)).

Then, a plating resist was formed in a pattern reverse to a conductive pattern on the surface of the metal thin film (see FIG. 2(c)).

Then, a first copper layer having a thickness of 3.0 μm was laminated on the surface of the metal thin film exposed from the plating resist by an electrolytic copper plating method.

Then a first silver layer having a thickness of 43.2 nm was laminated on the surface of the first copper layer exposed from the plating resist by an electroless silver plating method.

Then a second copper layer having a thickness of 2.0 μm was laminated on the surface of the first silver layer exposed from the plating resist by an electrolytic copper plating method.

Then a second silver layer having a thickness of 42.1 nm was laminated on the surface of the second copper layer exposed from the plating resist by an electroless silver plating method.

Then a third copper layer having a thickness of 3.3 μm was laminated on the surface of the second silver layer exposed from the plating resist by an electrolytic copper plating method.

Then, the plating resist was removed by etching. Thereafter, the metal thin film exposed from the laminate metal layer formed by laminating the first copper layer, the first silver layer, the second copper layer, the second silver layer, and the third copper layer was removed by etching (see FIG. 5).

Then, the silver contained in the first silver layer and the second silver layer was diffused into the first copper layer, the second copper layer, and the third copper layer by heating the laminate metal layer in a nitrogen atmosphere at 400° C. for 120 minutes, whereby the conductive pattern made of a copper alloy was formed (see FIG. 1(c) and FIG. 2(g)). The weight ratio of the silver diffused in the copper alloy was 1.02% by weight to the copper alloy.

Thereafter, a varnish of a photosensitive resin was coated on the insulating base layer, dried, exposed to light, developed, and then cured to form an insulating cover layer having a thickness of 5 μm on the insulating layer such that the conductive pattern was covered therewith and openings were formed therein to expose the terminal portions (see FIG. 1(d)).

### Comparative Example 1

A wired circuit board was obtained by the same procedure as in EXAMPLE 1 except that no silver layer was laminated and the thickness of the copper layer was changed to 8.3 μm.

### Example 7

A metal supporting board made of a stainless steel foil having a thickness of 25 μm was prepared.

Then, a varnish of a photosensitive resin was coated on the metal supporting board, dried, exposed to light, developed, and then cured to form an insulating base layer having a thickness of 10 μm on the metal supporting board.

Then, a chromium thin film having a thickness of 40 nm and a copper thin film having a thickness of 70 nm were successively formed on the surface of the insulating base layer by a sputtering method to form a metal thin film as a seed film on the insulating base layer.

Then, a plating resist was formed in a pattern reverse to a conductive pattern on the surface of the metal thin.

Then, a silver layer having a thickness of 70.0 nm was laminated on the surface of the metal thin film exposed from the plating resist by a silver sputtering method.

Then, a copper layer having a thickness of 8.1 μm was laminated on the surface of the silver layer by an electrolytic copper plating method.

Then, the plating resist was removed by etching and the metal thin film exposed from a laminate metal layer formed by laminating the silver layer and the copper layer was removed by etching.

Then, the silver contained in the silver layer was diffused into the copper layer by heating the laminate metal layer in a nitrogen atmosphere at 400° C. for 120 minutes, whereby the conductive pattern made of a copper alloy was formed. The weight ratio of the silver diffused in the copper alloy was 1.01% by weight to the copper alloy.

Thereafter, a varnish of a photosensitive resin was coated on the insulating base layer, dried, exposed to light, developed, and then cured to form an insulating cover layer having a thickness of 5 μm on the insulating layer such that the conductive pattern was covered therewith and openings were formed therein to expose the terminal portions.

Then, the metal supporting board was opened at the same positions as the openings in the insulating cover layer by etching. Subsequently, the insulating base layer exposed from the openings in the metal supporting board was opened by etching, whereby the terminal portions in a flying lead structure having the top surfaces exposed from the insulating cover layer and the back surfaces exposed from the metal supporting board and the insulating base layer were formed (see FIG. 6).

### Comparative Example 2

A wired circuit board was obtained by the same procedure as in EXAMPLE 1 except that the thickness of the silver layer was changed to 7.0 nm and the thickness of the copper layer was changed to 7.8 μm. The weight ratio of the silver diffused in the copper alloy was 0.09% by weight to the copper alloy.

### (Evaluation)

The tensile strengths of the wired circuit boards obtained in the examples and the comparative examples were measured using an RSAIII viscoelasticity measuring apparatus, the result of which is shown in Table 1.

TABLE 1

| | | | Example/Comparative Example | | | | | | | | |
|---|---|---|---|---|---|---|---|---|---|---|---|
| | | | | | | | | | | Com- | Com- |
| | | | | | | | | | | parative | parative |
| | | | Example 1 | Example 2 | Example 3 | Example 4 | Example 5 | Example 6 | Example 7 | Example 1 | Example 2 |
| Wired Circuit Board | | | Flexible Wired Circuit Board | | | | | | Suspension | Flexible | |
| | | | | | | | | | Board With | Wired Circuit Board | |
| | | | | | | | | | Circuit* | | |
| Laminate | Ag | Formation | Silver | | Electroless Silver Plating | | | | Silver | — | Silver |
| Metal | Layer | Method | Sputtering | | | | | | Sputtering | | Sputtering |
| Layer | | Laminate | Lowermost | | Sandwiched | | | Sandwiched | Lowermost | — | Lower- |
| | | Position | Portion | | (One Layer) | | | (Two Layers) | Portion | | most |
| | | | | | | | | | | | Portion |
| | Weight Ratio of Ag | | 0.51 | 0.82 | 0.53 | 0.93 | 1.66 | 1.02 | 1.01 | 0.00 | 0.09 |
| | After Heating (wt %) | | | | | | | | | | |
| | Thickness | Ag Layer | 35.0 | 70.0 | 40.0 | 92.8 | 155.8 | 43.2 | 70.0 | — | 7.0 |
| | (nm) | (First | | | | | | | | | |
| | | Ag Layer) | | | | | | | | | |
| | | Second | — | — | — | — | — | 42.1 | — | | — |
| | | Ag Layer | | | | | | | | | |
| | Thickness | Cu Layer | 8.1 | 8.5 | 4.3 | 4.5 | 4.3 | 3.0 | 8.1 | 8.3 | 7.8 |
| | (μm) | (First | | | | | | | | | |
| | | Cu Layer) | | | | | | | | | |
| | | Second | — | — | 4.6 | 5.3 | 4.9 | 2.0 | — | — | — |
| | | Cu Layer | | | | | | | | | |
| | | Third | | | — | — | — | 3.3 | | | |
| | | Cu Layer | | | | | | | | | |

| | | | | | | | | | | |
|---|---|---|---|---|---|---|---|---|---|---|
| Evaluation | Tensile | 143 | 163 | 193 | 189 | 198 | 241 | 160 | 139 | 139 |
| | Strength (MPa) | | | | | | | | | |

Suspension Board With Circuit (Example 7)*: Flying Lead Structure

In Table 1, the weight ratio of silver after heating shows the weight ratio of silver to the copper alloy in which the silver is diffused by heating and the value of each of the silver layers and the copper layers shows the thickness thereof.

As shown in Table 1, the results confirmed that the wired circuit board according to each of the examples which comprised the conductive pattern made of the copper alloy in which silver was diffused and contained at a content ratio of more than 0.50% by weight and not more than 3.00% by weight had a higher tensile strength than the wired circuit board according to each of the comparative examples which did not comprise a conductive pattern made of such a copper alloy.

In particular, a higher strength was observed in each of EXAMPLES 3 to 6 where the laminate layers each having the sandwich structure sandwiching the silver layer between the copper layers were formed.

In EXAMPLE 6 where the two silver layers sandwiched between the copper layers were formed, the one silver layer sandwiched between the copper layers was formed, whereby EXAMPLE 6 observes a much higher strength than that of Example 4 where the weight ratio of silver was relatively close to that of the copper alloy.

While the illustrative embodiments of the present invention are provided in the above description, such is for illustrative purpose only and it is not to be construed limitative. Modification and variation of the present invention that will be obvious to those skilled in the art is to be covered by the following claims.

What is claimed is:

1. A wired circuit board comprising:
an insulating layer; and
a conductive pattern formed on the insulating layer and made of a copper alloy in which silver is diffused, wherein a content ratio of the silver contained in the copper alloy is more than 0.50% by weight and not more than 3.00% by weight.

2. The wired circuit board according to claim 1, wherein the conductive pattern is obtained by laminating a silver layer and a copper layer on the insulating layer, and heating a resulting laminate thereafter.

3. The wired circuit board according to claim 1, wherein the conductive pattern is obtained by laminating a first copper layer, a silver layer and a second copper layer successively on the insulating layer, and heating a resulting laminate thereafter.

4. A method of producing a wired circuit board comprising the steps of:
preparing an insulating layer;
laminating a silver layer and a copper layer on the insulating layer; and
forming a conductive pattern made of a copper alloy by heating the silver layer and the copper layer to diffuse the silver in the copper, wherein a content ratio of the silver contained in the copper alloy is more than 0.50% by weight and not more than 3.00% by weight.

5. A method of producing a wired circuit board comprising the steps of:
preparing an insulating layer;
laminating a first copper layer, a silver layer and a second copper layer successively on the insulating layer; and
forming a conductive pattern made of a copper alloy by heating the first copper layer, the silver layer and the second copper layer to diffuse the silver in the copper, wherein a content ratio of the silver contained in the copper alloy is more than 0.50% by weight and not more than 3.00% by weight.
